(19) United States
(12) Patent Application Publication
(10) Pub. No.: US 2015/0116801 A1
(43) Pub. Date: Apr. 30, 2015

(54) SINGLE LONGITUDINAL MODE DIODE LASER MODULE WITH EXTERNAL RESONATOR

(71) Applicant: SHOWA OPTRONICS CO., LTD., Tokyo (JP)

(72) Inventors: Minoru Kadoya, Tokyo (JP); Kenji Ohara, Yokohama-shi (JP)

(73) Assignee: SHOWA OPTRONICS CO., LTD., Tokyo (JP)

(21) Appl. No.: 14/191,390

(22) Filed: Feb. 26, 2014

(30) Foreign Application Priority Data
Oct. 28, 2013 (JP) 2013-223076

(51) Int. Cl. H01S 5/00; H01S 5/024

(52) U.S. Cl. CPC H01S 5/005; H01S 5/024
USPC 359/15

(57) ABSTRACT

A single longitudinal mode diode laser module including a laser diode (1) and an external resonator using a volume holographic grating (3) having a prescribed reflective bandwidth is made amenable to automatic power control by controlling the temperature of the laser diode such that the laser power may be allowed to increase monotonically with an increase in the input current. Therefore, the output laser power can be controlled at a constant level by automatic power control or by adjusting the input current while monitoring the laser power at any desired level of the laser power.

### TECHNICAL FIELD

The present invention relates to a diode laser module provided with an external resonator using a volume holographic grating (VHG) for controlling the wavelength.

### PRIOR ART

Laser diodes that emit laser light by injection of electric current by using semiconductor as a gain medium are known to demonstrate wide variations in the central wavelength of the emitted laser light. The mass produced, commercially available laser diodes are typically given with a tolerance of ±3 nm to ±5 nm in the central wavelength. The central wavelength of a laser diode is also affected by the input current and the temperature.

Some of the commercially available laser diodes with central wavelengths greater than 1 μm are configured to operate in a single longitudinal mode by providing a periodic structure near an active region of the waveguide structure, but a great majority of the commercially available laser diodes with central wavelengths less than 1 μm are configured to operate in a multi longitudinal mode involving a plurality of longitudinal modes.

There may be applications where the variations and changes in the central wavelength of the laser diode are not a problem. However, in the applications for analysis and measurement, even small variations and changes in the central wavelength are not acceptable in some cases, and single mode operation is essential, instead of multiple mode operation.

A proposal has been made to control the central wavelength of a laser diode and achieve a single longitudinal mode operation by using a volume holographic grating (VHG). See U.S. Pat. No. 7,636,376, for instance. The volume holographic grating is also known as a volume Bragg grating (VBG). The volume holographic grating consists of a glass element having a periodic change in the refractive index thereof along a prescribed direction, and has the property to reflect light of a particular incident angle such that the reflected light has a particular wavelength. According to the invention disclosed in U.S. Pat. No. 7,636,376, output light of a laser diode is directed vertically onto the volume holographic grating, and the light reflected thereby is coupled to the laser diode so that the operating wavelength of the laser diode is controlled to a prescribed wavelength determined by the property of the volume holographic grating, and the laser diode is operated in a single longitudinal mode.

Another example of a laser module using an optical diffraction grating is disclosed in U.S. Pat. No. 5,594,744. In this example, the use is made of the property of the diffraction grating which propagates the laser light in wavelength dependent directions. In particular, the diffracted light which has propagated in a certain direction is reflected back to the laser diode by adjusting the angle of a reflective mirror so as to couple the diffracted light of a prescribed wavelength with the laser diode.

An example of a laser module using prisms is disclosed in “Tunable Laser Applications” by Frank J. Duarte, 2nd edition, CRC Press, 2008, Chapter 5. This prior art is similar to that disclosed in U.S. Pat. No. 5,594,744 in that the wavelength selection is achieved by the use of an optical diffraction grating. However, to further improve the wavelength selectivity, the cross sectional shape of the beam of laser light is expanded in a prescribed direction by using a plurality of prisms before being made incident to the optical diffraction grating.

An example of laser using an Etalon device is disclosed in “Fujifilm Research & Development”, No. 49, pp. 26-31, 2004. A reflective mirror is placed on a side of the laser diode away from the end from which laser light is taken out. A band pass filter having a highly selective transmissivity is interposed between the laser diode and the reflective mirror so as to achieve a single longitudinal mode operation, and the wavelength of the laser light is adjusted by changing the angle of the band pass filter.

According to these conventional laser modules, a mode hop occurs when the input current to the laser diode is changed for the purpose of adjusting the laser power. As a result, the laser power does not monotonically increases with an increase in the input current, but cyclically increases and decreases with an increase in the input current. When driving a laser diode, it is customary to perform an automatic power control (APC) whereby the input current is controlled while monitoring the laser power so that the laser power may be maintained at a fixed level. However, if the laser power does not increase monotonically with an increase in the input current, it is difficult to execute an automatic power control in a stable manner.

In the example disclosed in “Fujifilm Research & Development”, high frequency current is superimposed on the input current of the laser diode so that multi longitudinal mode operation may be achieved. Thereby, the laser power is allowed to monotonically increase with the increase in the input current, and the automatic power control can be performed in a stable manner while the adverse influences of mode hopping is minimized. Superimposing high frequency current on the input current of the laser diode is an effective approach in applications where multi longitudinal mode operation creates no problem, but is not suitable for use in applications where single longitudinal mode operation is essential.

### BRIEF SUMMARY OF THE INVENTION

In view of such problems of the prior art, a primary object of the present invention is to provide a single longitudinal mode diode laser module which is amenable to automatic power control.

To achieve such an object, the present invention provides a single longitudinal mode diode laser module including a laser diode and an external resonator using a volume holographic grating having a prescribed reflective bandwidth, including: a temperature control unit for controlling a temperature of the laser diode at a prescribed temperature; a first monitoring unit configured to monitor a first laser power of laser light reflected by the volume holographic grating and output a first signal indicating the first laser power; and a second monitoring unit configured to monitor a second laser power of laser light transmitted by the volume holographic grating and output a second signal indicating the second laser power; wherein the first signal and the second signal are adjusted such that the first signal and the second signal are equal to each other at a desired operating point of the diode laser module, and wherein the temperature control unit increases the temperature of the laser diode above the prescribed temperature when the first signal is greater than the second signal, and decreases the temperature of the laser diode below the prescribed temperature when the first signal is smaller than the second signal.

According to a certain aspect of the present invention, the diode laser module further includes a collimator lens for collimating laser light emitted from the laser diode, a first beam splitter configured to receive laser light collimated by the collimator lens and transmit the laser light to the volume holographic grating and a second beam splitter for receiving the laser light transmitted by the volume holographic grating, part of the laser light reflected by the volume holographic grating being coupled to an active region of the laser diode via the first beam splitter and the collimator lens, and laser light transmitted by the second beam splitter providing output laser light of the diode laser module, wherein the first monitoring unit is configured to receive laser light reflected by the volume holographic grating and the first beam splitter, and the second monitoring unit is configured to receive laser light transmitted by the volume holographic device and reflected by the second beam splitter.

According to a another aspect of the present invention, the diode laser module further includes a collimator lens for collimating laser light emitted from the laser diode, an anamorphic prism pair configured to receive laser light collimated by the collimator lens and transmit the laser light to the volume holographic grating and a beam splitter for receiving the laser light transmitted by the volume holographic grating, part of the laser light reflected by the volume holographic grating being coupled to an active region of the laser diode via the anamorphic prism pair and the collimator lens, and laser light transmitted by the beam splitter providing output laser light of the diode laser module, wherein the first monitoring unit is configured to receive laser light reflected by the volume holographic grating and an output end of the anamorphic prism pair, and the second monitoring unit is configured to receive laser light transmitted by the volume holographic device and reflected by the beam splitter.

In this case, the anamorphic prism pair may be configured such that the cross section of the beam of laser light leaving the anamorphic prism pair is made substantially circular. Thus, the anamorphic prism pair may provide the functions of a beam splitter and a beam shaper at the same time.

According to the present invention, the laser diode which normally operates in a multi longitudinal mode can be operated in a single longitudinal mode by using a volume holographic grating so that the laser power may be allowed to increase monotonically with an increase in the input current. Therefore, the output laser power can be controlled at a constant level by automatic power control or by adjusting the input current while monitoring the laser power at any desired level of the laser power. Even when the laser diode may degenerate over time, and the levels of the input current (forward current) and the forward voltage required for a prescribed laser power output may vary, an optimum operating point can be maintained automatically at all times. Furthermore, these advantages can be gained by using a highly simple structure and a highly simple control arrangement.

### BRIEF DESCRIPTION OF THE DRAWINGS

FIG. 1 is a schematic diagram showing the structure of a first embodiment of the diode laser module according to the present invention;

FIG. 2 is a graph showing the properties of the transmissivity and reflectivity of a volume holographic grating shown in FIG. 1 in relation with wavelength;

FIG. 3 is a graph showing the power of light inside and outside of an external resonator of the diode laser module shown in FIG. 1;

FIG. 4 is a diagram illustrating the process of obtaining an error signal required for a negative feedback control of the diode laser module shown in FIG. 1;

FIG. 5 is a schematic diagram of an optical system of a second embodiment of the present invention; and

FIG. 6 is a view similar to FIG. 1 showing a third embodiment of the diode laser module according to the present invention.

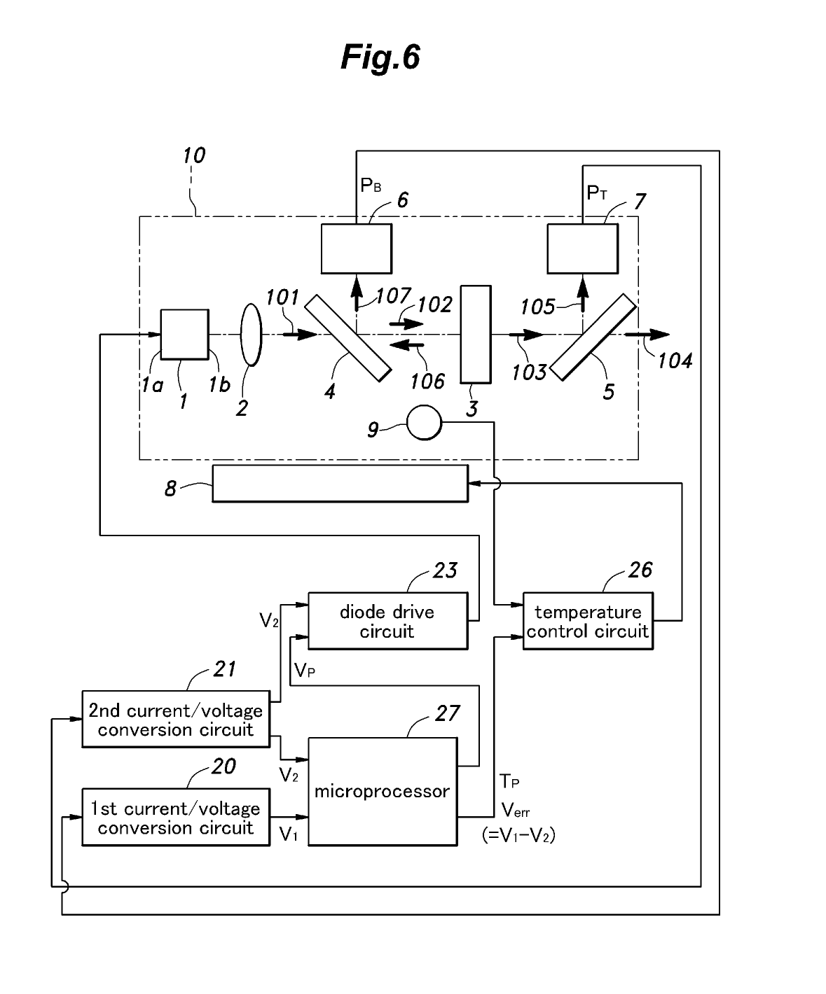

### DETAILED DESCRIPTION OF THE PREFERRED EMBODIMENTS

### First Embodiment

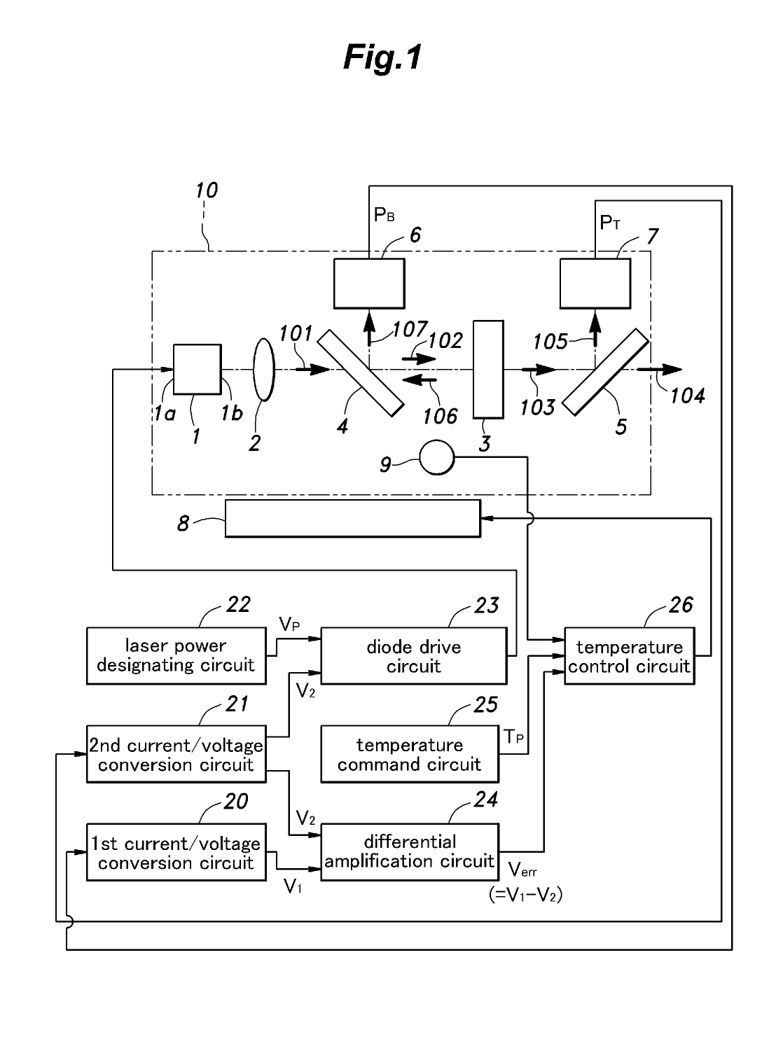

FIG. 1 shows both the optical system and the electronic system of a single longitudinal mode diode laser module provided with an external resonator according to the present invention.

A laser diode 1 consists of an InGaN diode having a gain peak wavelength of 405 nm. A first end 1a of an active layer of the laser diode 1 is provided with a high reflectance coating having a reflectance of 95% or higher for the wavelength of 405 nm, and the second end 1b thereof is provided with a low reflectance coating having a reflectance of 1% or less for the wavelength of 405 nm. When adequate electric current input is received, this laser diode 1 is able to emit laser light by itself without the aid of external optical devices. The laser diode 1, when operated by itself, operates under a mutli longitudinal mode, and the mode spacing in wavelength is given by the free spectral range which is determined by the resonator length of the laser diode 1. The value of the free spectral range of this laser diode 1 is 28 pm.

A collimator lens 2 consisting of an aspherical lens is placed opposite to the second end 1b of the laser diode 1 with the low reflectance coating to collimate the laser light emitted from the laser diode 1. The cross sectional shape of the collimated beam of the laser light 101 is elliptic in shape, and the major axis/minor axis ratio of the ellipse is approximately 2.

The collimated laser light 101 is made incident to a first light splitter 4 at a 45 degree angle, and the laser light 102 transmitted thereby is then made incident to a volume holographic grating 3. The volume holographic grating 3 consists of a piece of special glass having a periodic change in refractive index along a prescribed direction, and contains about 20,000 cycles of refractive grating within the thickness of about 3 mm in this case. The volume holographic grating 3 has a reflectance peak at a wavelength of 405 nm, and the peak value is approximately 20%. In an example, the nominal bandwidth (a bandwidth between the points where the reflectance is one half of the peak value) of the volume holographic grating 3 specified by the manufacturer was 100 pm or less, but was found to be as narrow as approximately 30 pm according to the actual measurement. The nominal bandwidth may be also referred to as a reflective bandwidth.

Owing to this wavelength property of the volume holographic grating 3, a single longitudinal mode can be achieved by selectively reflecting longitudinal mode laser light 106 having a wavelength contained in the reflective band of the volume holographic grating 3 from among the entire longitudinal modes of the laser light 102 emitted from the laser diode 1 and transmitted to the volume holographic grating 3, and coupling the reflected laser light 106 to the active region of the laser diode 1.

The laser light 106 reflected by the volume holographic grating 3 is in part reflected by the first beam splitter 4, and laser light 107 thus reflected by the first beam splitter 4 is received by a first light detector 6 which measures the intensity of the laser light 107. Laser light 103 that has passed through the volume holographic grating 3 is made incident to a second beam splitter 5, and laser light that passes through the second beam splitter 5 provides output laser light 104. Laser light 105 reflected by the second beam splitter 5 is received by a second light detector 7 which measures the intensity of the laser light 105.

The various components forming the external resonator discussed above are accommodated in a single metallic casing 10 which is temperature controlled by an electronic cooling device 8 based on the Peltier effect. A thermistor 9 is embedded in the metallic casing 10 so that the electronic cooling device 8 is controlled by a temperature control circuit 26 according to the temperature of the metallic casing 10 detected by the thermistor 9. Thereby, the temperature of the metallic casing 10 or the temperature of the external resonator is maintained at a prescribed temperature T_{P} designated by a temperature command circuit 25. As will be appreciated from the following description, for the purpose of the present invention, only the temperature of the laser diode 1 is required to be controlled. However, for the convenience of implementation, the temperature of the laser diode 1 may be indirectly controlled via the metallic casing 10 or any other components that are in thermal contact with the laser diode 1.

The laser power P_{B} of the laser light 106 reflected by the volume holographic grating 3 is indirectly monitored by the first light detector 6 which detects the laser light 107 reflected by the first light splitter 4. The photocurrent generated by the first light detector 6 (indicating the detected laser power P_{B}) is converted into a first voltage V₁ by a first current/voltage conversion circuit 20 after suitable amplification or attenuation, and the first voltage V₁ is forwarded to a differential amplification circuit 24.

The laser power of the output laser light 104 is indirectly measured by the second light detector 7 which detects the laser light 105 reflected by the second beam splitter 5. The intensity of the reflected laser light 105 is proportional to the intensity of the laser light 103 that has passed through the volume holographic grating 3 and is incident to the beam splitter 5. The laser power of the output laser light 104 is given by the laser power P_{T} of the laser light 103 minus the loss caused by the transmissivity of the second beam splitter 5, and can be equated to the laser power P_{T} of the laser light 103 by bringing the transmissivity close to 1. Therefore, in the following description, it is assumed that the laser powers of the laser light 103 and the laser light 104 are essentially the same. The photocurrent generated by the second light detector 7 (indicating the detected laser power P_{T} of the laser light 104) is converted into a second voltage V₂ by a second current/voltage conversion circuit 21 after suitable amplification or attenuation, and the second voltage V₂ is forwarded to a diode drive circuit 23 as well as to the other input end of the differential amplification circuit 24.

The diode drive circuit 23 increases the input current supplied to the laser diode 1 when the second voltage V₂ produced by the second current/voltage conversion circuit 21 is lower than a voltage (referred to as a set voltage V_{P} hereinafter) corresponding to the laser power designated by a laser power designating circuit 22, and decreases the input current supplied to the laser diode 1 when the second voltage V₂ is higher than the set voltage V. As a result, the laser power P_{T} of the laser light 104 is automatically maintained at the level of laser power designated by the laser power designating circuit 22.

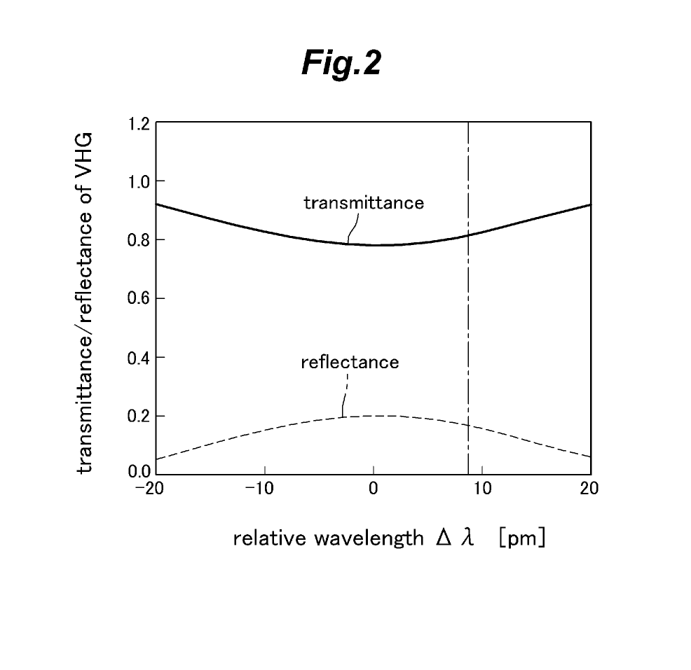

FIG. 2 shows the properties of the transmittance and reflectance of the volume holographic grating 3 in relation with wavelength λ. The abscissa is given by relative wavelength Δλ with respect to a base wavelength at which the reflectance of the volume holographic grating 3 is maximized.

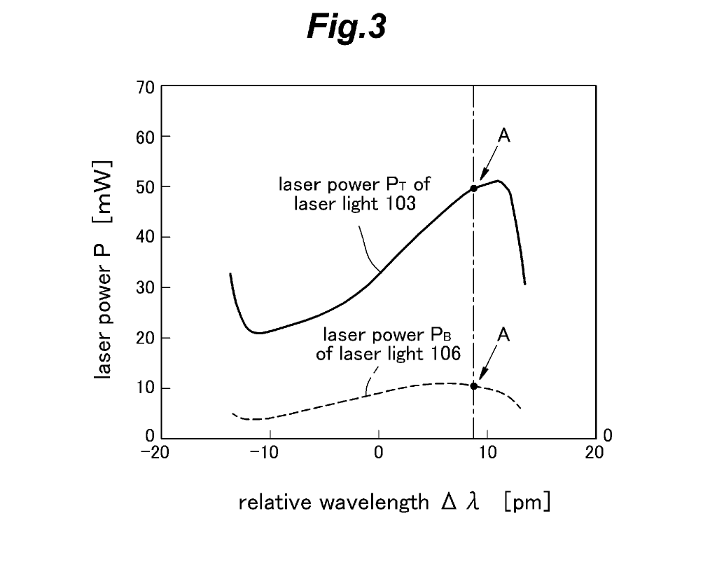

FIG. 3 shows the relationship between the laser wavelength (relative wavelength Δλ) and the laser power of the laser light when the temperature of the metallic casing 10 is changed while the input current of the laser diode 1 is kept constant. The solid line curve indicates the laser power P_{T} of the laser light 103 transmitted by the volume holographic grating 3. The broken line curve indicates the laser power P_{B} of the laser light 106 reflected by the volume holographic grating 3. As the temperature is raised, the operating point shifts toward a longer wavelength side, and upon reaching the right end of the curve, the mode hops to the wavelength at the left end of the curve. When the temperature is raised further, the operating point shifts toward a longer wavelength side, and eventually returns to the original operating point (wavelength). This cycle of operating point shift repeats itself for each increase of the temperature by 2 degrees C.

When the input current is gradually increased while the temperature is kept fixed, the laser power P_{T} of the laser light 103 and the laser power P_{B} of the laser light 106 change similarly as those indicated by the solid line and broken line in FIG. 3, respectively. As the input current is increased, the operating point shifts toward a longer wavelength side, and upon reaching the right end of the curve, the mode hops to the wavelength at the left end of the curve. When the input current is increased further, the operating point shifts toward a longer wavelength side, and eventually returns to the original operating point (wavelength). Because the input current continually increases during this process, the laser powers P_{T} and P_{B} increase in a corresponding manner from one cycle to the next. This cycle of operating point shift repeats itself for each increase of the input current by about 20 mA.

When raising the temperature or increasing the input current, a maximum laser power for a given input current can be obtained at a positive relative wavelength Δλ near the wavelength where a mode hop occurs. In the case of the property shown in FIG. 3, an optimum operating point A can be obtained approximately at a relative wavelength of +9 pm as indicated by the chain dot line.

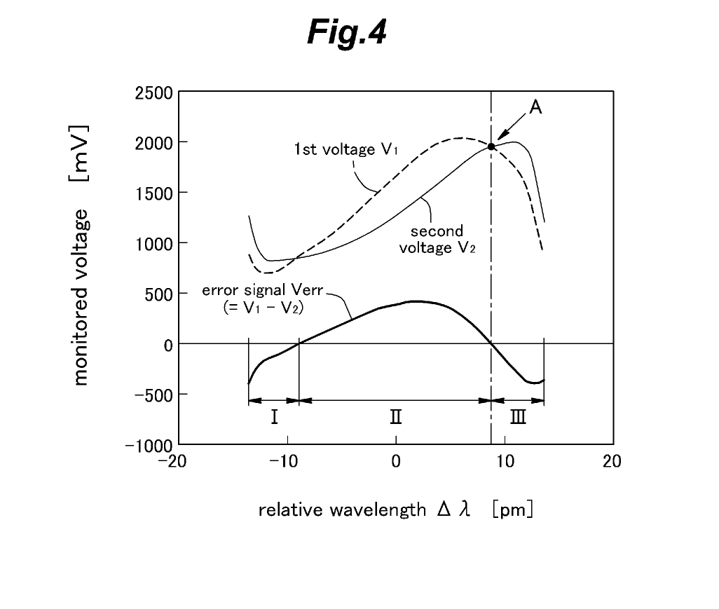

How an error signal Vₑᵣᵣ for performing an automatic control to maintain this optimum operating point A can be obtained is described in the following with additional reference to FIG. 4. As shown in FIG. 1, the laser powers P_{B} and P_{T} indirectly detected by the first optical detector 6 and the second optical detector 7 are converted into the first voltage V₁ and the second voltage V₂ by the first current/voltage conversion circuit 20 and the second current/voltage conversion circuit 21, respectively, where the conversion circuits 20 and 21 have gains individually adjusted such that the two voltages V₁ and V₂ are equal to each other at the optimum operating point A. In FIG. 4, the first voltage V₁ and the second voltage V₂ are both equal to 2,000 mV at the optimum operating point A.

If the set temperature T_{P} is intentionally changed while the input current (or forward current) is kept constant, the first voltage V₁ and the second voltage V₂ will change as indicated by the broke line and the solid line, respectively, in FIG. 4. Therefore, the difference V₁−V₂ between the two voltages (or the error signal Vₑᵣᵣ) changes as indicated by the bold line in FIG. 4. More specifically, the error signal Vₑᵣᵣ also changes cyclically with the change in the temperature. In each cycle, the error signal Vₑᵣᵣ is positive in a certain range indicated by II in FIG. 4, and is negative in the remaining range indicated by I and III.

As shown in FIG. 1, the error signal Vₑᵣᵣ calculated by the differential amplification circuit 24 is forwarded to the temperature control circuit 26, and the set temperature T_{P} designated by the temperature command circuit 25 is also forwarded to the temperature control circuit 26. The temperature control circuit 26 controls the temperature of the metallic casing 10 by using the electronic cooling device 8 according to the set temperature T_{P} and the error signal Vₑᵣᵣ as will be described in the following.

Suppose that the set temperature T_{P} deviates from the optimum temperature when the temperature control is being executed by the temperature control circuit 26 as shown in FIG. 1. If the operating point is in region II in FIG. 4, the error signal Vₑᵣᵣ is positive in value so that the temperature control circuit 26 increases the temperature of the metallic casing 10 by controlling the electronic cooling device 8 (preferably by a value proportional to the absolute value of the error signal Vₑᵣᵣ). As a result, the operating point of the longitudinal mode operation of the laser diode 1 shifts toward longer wavelength so that the operating point moves from the side of shorter wavelength toward the optimum operating point A. If the operating point is in region III in FIG. 4, the error signal Vₑᵣᵣ is negative in value so that the temperature control circuit 26 decreases the temperature of the metallic casing 10 by controlling the electronic cooling device 8 (preferably by a value proportional to the absolute value of the error signal Vₑᵣᵣ). As a result, the operating point of the longitudinal mode operation of the laser diode 1 shifts toward a shorter wavelength so that the operating point moves from the side of longer wavelength toward the optimum operating point A.

If the operating point is in region I in FIG. 4, the error signal Vₑᵣᵣ is negative in value so that the temperature control circuit 26 decreases the temperature of the metallic casing 10 by controlling the electronic cooling device 8. As a result, the operating point of the longitudinal mode operation of the laser diode 1 shifts toward a shorter wavelength, but upon reaching the left end of the curve, jumps back to the right end of the curve owing to a mode hop so that the operating point eventually moves from the side of longer wavelength toward the optimum operating point A, similarly as with the case where the original operating point was located in region III.

As discussed above, the temperature control circuit 26 controls the temperature of the metallic casing 10 by using the electronic cooling device 8 such that the temperature of the metallic casing 10 is raised above the set temperature T_{P} when a positive error signal is received and is lowered below the set temperature T_{P} when a negative error signal is received, each in a corresponding manner. Thereby, the laser power of the output laser power 104 (which is directly related to the laser power P_{T} of the laser light 103 that passes through the volume holographic grating 3) can be optimized at all times. The obtained output laser power increases monotonically in relation with the input current. Therefore, without regard to the level of laser power designated by the laser power designating circuit 22, an automatic power control (APC) is enabled such that the laser power P_{T} is monitored and maintained at a fixed level by adjusting the input current.

### Second Embodiment

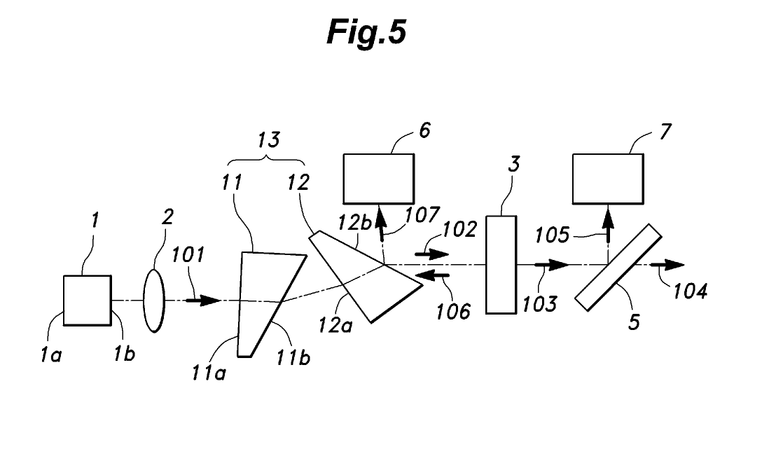

FIG. 5 shows a second embodiment of the single longitudinal mode diode laser module according to the present invention. In FIG. 5, the parts corresponding to those of the first embodiment are denoted with like numerals without necessarily repeating the description of such parts. The second embodiment is similar to the first embodiment in using a laser diode 1, a collimator lens 2, a volume holographic grating 3, a second beam splitter 5, a first light detector 6 and a second light detector 7, and these components are essentially the same as those of the first embodiment. However, the first beam splitter 4 is not used, and an anamorphic prism pair 13 consisting of a first prism 11 and a second prism 12 are used instead.

The cross sectional shape of the beam of the laser light 101 collimated by the collimator lens 2 is elliptic in shape, and the major axis/minor axis ratio of the ellipse is approximately 2. The anamorphic prism pair 13 reduces the beam of the laser light 101 in the major axis direction by one half so that the laser light 102 that has passed through the anamorphic prism pair 13 is shaped into a laser beam having a substantially circular cross section.

The two faces 11a and 11b of the first prism 11 through which the laser light passes are coated with a low reflectance coating. One of the faces 12b of the second prism 12 through which the laser light passes facing the volume holographic grating 3 is coated with a partial reflective coating which reflects about 1% of the incident laser light 106. The other face 12a of the second prism 12 is coated with a low reflectance coating. Therefore, a fraction 107 of the laser light 106 reflected by the volume holographic grating 3 is reflected by the partial reflective coating of the second prism 12, and is received by the first light detector 6 so that the intensity of the laser light 107 is measured by the first light detector 6 to provide a measure of the laser power P_{B} of the laser light 106 reflected by the volume holographic grating 3. Laser light 105 reflected by the second beam splitter 5 is received by the second light detector 7 to provide a measure of the laser power P_{T} of the output laser light 104.

According to this embodiment, the anamorphic prism pair 13 not only shapes the beam of the laser light into a circular cross section but also serves as a beam splitter corresponding to the first beam splitter 4 of the first embodiment.

### Third Embodiment

The optical arrangement of the third embodiment is identical to that of the first embodiment. The third embodiment includes a first current/voltage conversion circuit 20, a second current/voltage conversion circuit 21, a diode drive circuit 23 and a temperature control circuit 26 which are no different from the counterparts of the first embodiment. The third embodiment however does not include the laser power designating circuit 22, the differential amplification circuit 24 and the temperature designating circuit 25, and includes a microprocessor 27 that provides the functions of an analog-digital converter (ADC) and a digital-analog converter (DAC).

The laser power associated with the set voltage V_{P} may be stored in the internal memory of the microprocessor 27, or may be given to the microprocessor 27 externally via a communication link (not shown in the drawings). This value (laser power) is produced from the DAC as the set voltage V_{P}, and is forwarded to the diode drive circuit 23. The diode drive circuit 23 also receives the second voltage V₂ from the second current/voltage conversion circuit 21, and increases the input current to the laser diode 1 when the second voltage V₂ is lower than the set voltage V_{P}, and decreases the input current to the laser diode 1 when the second voltage V₂ is higher than the set voltage V_{P}. Owing to this control action, the laser power of the output laser light 104 is maintained at a fixed value designated by the microprocessor 27.

The set temperature T_{P} may be retained in the internal memory of the microprocessor 27 or given externally via a communication link. The microprocessor 27 converts the first voltage V₁ obtained from the first current/voltage conversion circuit 20 and the second voltage V₂ obtained from the second current/voltage conversion circuit 21 into corresponding digital signals (thus, the microprocessor 27 functions as an ADC), and computes the error signal Vₑᵣᵣ as a difference between the two voltages (V₁−V₂). The microprocessor 27 constantly monitors the first and second voltages V₁ and V₂, and hence the error signal Vₑᵣᵣ. When the error signal Vₑᵣᵣ output from the microprocessor 27 is positive, the temperature control circuit 26 raises the temperature of the metallic casing 10 from the set temperature T_{P} by a value corresponding to the absolute value of the error signal Vₑᵣᵣ. Conversely, when the error signal Vₑᵣᵣ is negative, the temperature control circuit 26 lowers the temperature of the metallic casing 10 from the set temperature T_{P} by a value corresponding to the absolute value of the error signal Vₑᵣᵣ. Then, when the absolute value of the error signal Vₑᵣᵣ becomes smaller than a predetermined value, the temperature control circuit 26 stops the raising or lowering of the temperature of the metallic casing 10 from the set temperature T_{P}. Owing to such an operation, the operating point of the longitudinal mode operation of the laser diode 1 can be maintained at an optimum point.

Although the present invention has been described in terms of preferred embodiments thereof, it is obvious to a person skilled in the art that various alterations and modifications are possible without departing from the scope of the present invention which is set forth in the appended claims. For example, the optical system of the second embodiment may also be applied to the third embodiment. Further, in the first embodiment also, it is possible to set threshold values for determining when to start and stop raising and/or lowering of the temperature of the metallic casing 10, or to adjust an amount of temperature increase and/or decrease in accordance with the absolute value of the error signal Vₑᵣᵣ in a similar manner as in the third embodiment. The threshold value for starting raising or lowering of the temperature may be different from the threshold value for stopping raising or lowering of the temperature. The concrete shape, arrangement, material, and/or characteristics of each member/part constituting the diode laser module may be altered or modified as appropriate without departing from the spirit of the present invention. Further, not all of the elements shown in the foregoing embodiments are necessarily indispensable, and they may be selectively used as appropriate.

The contents of the original Japanese patent application on which the Paris Convention priority claim is made for the present application as well as the contents of the prior art references mentioned in this application are incorporated in this application by reference.

1. A single longitudinal mode diode laser module including a laser diode and an external resonator using a volume holographic grating having a prescribed reflective bandwidth, comprising:
a temperature control unit for controlling a temperature of the laser diode at a prescribed temperature;
a first monitoring unit configured to monitor a first laser power of laser light reflected by the volume holographic grating and output a first signal indicating the first laser power; and
a second monitoring unit configured to monitor a second laser power of laser light transmitted by the volume holographic grating and output a second signal indicating the second laser power;
wherein the first signal and the second signal are adjusted such that the first signal and the second signal are equal to each other at a desired operating point of the diode laser module, and
wherein the temperature control unit increases the temperature of the laser diode above the prescribed temperature when the first signal is greater than the second signal, and decreases the temperature of the laser diode below the prescribed temperature when the first signal is smaller than the second signal.

2. The single longitudinal mode diode laser module according to claim 1, further comprising a collimator lens for collimating laser light emitted from the laser diode, a first beam splitter configured to receive laser light collimated by the collimator lens and transmit the laser light to the volume holographic grating and a second beam splitter for receiving the laser light transmitted by the volume holographic grating,
part of the laser light reflected by the volume holographic grating being coupled to an active region of the laser diode via the first beam splitter and the collimator lens, and laser light transmitted by the second beam splitter providing output laser light of the diode laser module,
wherein the first monitoring unit is configured to receive laser light reflected by the volume holographic grating and the first beam splitter, and the second monitoring unit is configured to receive laser light transmitted by the volume holographic device and reflected by the second beam splitter.

3. The single longitudinal mode diode laser module according to claim 1, further comprising a collimator lens for collimating laser light emitted from the laser diode, an anamorphic prism pair configured to receive laser light collimated by the collimator lens and transmit the laser light to the volume holographic grating and a beam splitter for receiving the laser light transmitted by the volume holographic grating,
part of the laser light reflected by the volume holographic grating being coupled to an active region of the laser diode via the anamorphic prism pair and the collimator lens, and laser light transmitted by the beam splitter providing output laser light of the diode laser module,
wherein the first monitoring unit is configured to receive laser light reflected by the volume holographic grating and an output end of the anamorphic prism pair, and the second monitoring unit is configured to receive laser light transmitted by the volume holographic device and reflected by the beam splitter.
